(19) United States
(12) Patent Application Publication
(10) Pub. No.: US 2022/0013423 A1
(43) Pub. Date: Jan. 13, 2022

(54) ELECTRONIC DEVICE AND MANUFACTURING METHOD THEREOF

(71) Applicant: INNOSCIENCE (ZHUHAI) TECHNOLOGY CO., LTD., Zhuhai City (CN)

(72) Inventor: ANBANG ZHANG, Zhuhai City (CN)

(21) Appl. No.: 16/981,295

(22) PCT Filed: Jul. 8, 2020
(86) PCT No.: PCT/CN2020/100800

§ 371 Date: Sep. 16, 2020

(51) Int. Cl. H01L 23/31; H01L 29/778; H01L 23/29; H01L 29/66

(52) U.S. Cl. CPC H01L 23/3171; H01L 23/3192; H01L 29/42316; H01L 23/291; H01L 29/66462; H01L 29/7786

(57) ABSTRACT

Some embodiments of the disclosure provide an electronic device. The electronic device comprises: a substrate; a first nitride semiconductor layer on the substrate; a second nitride semiconductor layer on the first nitride semiconductor layer, and having a band gap greater than a band gap of the first nitride semiconductor layer; a group III-V dielectric layer disposed on the second nitride semiconductor layer; a gate electrode disposed on the second nitride semiconductor layer; and a first passivation layer disposed on the group III-V dielectric layer, wherein the group III-V dielectric layer is separated from the gate electrode by the first passivation layer.

### BACKGROUND

### 1. Technical Field

The disclosure is related to a semiconductor device, and in particular, to a semiconductor device including a high-electron-mobility transistor (HEMT).

### 2. Description of the Related Art

A semiconductor component including a direct band gap, for example, a semiconductor component including a group III-V material or group III-V compounds, may operate or work under a variety of conditions or environments (for example, different voltages or frequencies) due to its characteristics.

The foregoing semiconductor component may include an HEMT, a heterojunction bipolar transistor (HBT), a heterojunction field effect transistor (HFET), or a modulation-doped field effect transistor (MODFET).

### SUMMARY

Some embodiments of the disclosure provide an electronic device. The electronic device comprises: a substrate; a first nitride semiconductor layer on the substrate; a second nitride semiconductor layer on the first nitride semiconductor layer and having a band gap greater than a band gap of the first nitride semiconductor layer; a group III-V dielectric layer disposed on the second nitride semiconductor layer; a gate electrode disposed on the second nitride semiconductor layer; and a first passivation layer disposed on the group III-V dielectric layer, wherein the group III-V dielectric layer is separated from the gate electrode by the first passivation layer.

Some embodiments of the disclosure provide an electronic device. The electronic device includes a substrate and a transistor. The transistor includes a first nitride semiconductor layer disposed on the substrate, and a second nitride semiconductor layer disposed on the first nitride semiconductor layer and having a bandgap greater than that of the first nitride semiconductor layer. The transistor further includes a source electrode, a drain electrode and a gate electrode disposed directly on the second nitride semiconductor layer, and a multi-layer passivation disposed on the second nitride semiconductor layer. The multi-layer passivation includes a surface state compensating layer directly disposed on the second nitride semiconductor layer, and a low-k dielectric layer disposed on the surface state compensating layer.

Some embodiments of the disclosure provide an electronic device. The electronic device includes a substrate, a first nitride semiconductor layer disposed on the substrate, a second nitride semiconductor layer disposed on the first nitride semiconductor layer and having a bandgap greater than that of the first nitride semiconductor layer, and a multi-layer passivation disposed on the second nitride semiconductor layer, wherein the multi-layer passivation comprises a silicon nitride layer directly disposed on the second nitride semiconductor layer and a low-k dielectric layer disposed on the silicon nitride layer.

Some embodiments of the disclosure provide a method for forming an electronic device. The method includes providing a substrate, forming a first nitride semiconductor layer on a substrate, forming a second nitride semiconductor layer on the first nitride semiconductor layer, wherein the second nitride semiconductor layer has a bandgap greater than that of the first nitride semiconductor layer, and forming a multi-layer passivation on the second nitride semiconductor layer. The step of forming a multi-layer passivation includes forming a silicon nitride layer directly on the second nitride semiconductor layer, forming a low-k dielectric layer on the silicon nitride layer, and forming a source electrode, a gate electrode and a drain electrode of a transistor, wherein the gate electrode is disposed directly on the second nitride semiconductor layer.

### BRIEF DESCRIPTION OF THE DRAWINGS

Aspects of the disclosure will become more comprehensible from the following detailed description made with reference to the accompanying drawings. It should be noted that, various features may not be drawn to scale. In fact, the sizes of the various features may be increased or reduced arbitrarily for the purpose of clear description.

FIG. 1A illustrates a cross-sectional view of an electronic device in accordance with some embodiments of the present disclosure.

FIG. 1B illustrates capacitances of an electronic device in accordance with some embodiments of the present disclosure.

FIG. 2 illustrates a cross-sectional view of an electronic device in accordance with some embodiments of the present disclosure.

FIG. 3 illustrates a cross-sectional view of an electronic device in accordance with some comparative embodiments of the present disclosure.

FIG. 4A illustrates a step of a method for manufacturing an electronic device in accordance with some embodiments of the present disclosure.

FIG. 4B illustrates a step of a method for manufacturing an electronic device in accordance with some embodiments of the present disclosure.

FIG. 4C illustrates a step of a method for manufacturing an electronic device in accordance with some embodiments of the present disclosure.

FIG. 4D illustrates a step of a method for manufacturing an electronic device in accordance with some embodiments of the present disclosure.

FIG. 4E illustrates a step of a method for manufacturing an electronic device in accordance with some embodiments of the present disclosure.

### DETAILED DESCRIPTION

The following disclosure provides many different embodiments or examples for implementing different features of the provided subject matter. Specific examples of components and arrangements are described below. Certainly, these descriptions are merely examples and are not intended to be limiting. In the disclosure, in the following descriptions, the description of the first feature being formed on or above the second feature may include an embodiment in which the first feature and the second feature are formed to be in direct contact, and may further include an embodiment in which an additional feature may be formed between the first feature and the second feature to enable the first feature and the second feature to not be in direct contact. In addition, in the disclosure, reference numerals and/or letters may be repeated in examples. This repetition is for the purpose of simplification and clarity, and does not indicate a relationship between the described various embodiments and/or configurations.

The embodiments of the disclosure are described in detail below. However, it should be understood that many applicable concepts provided by the disclosure may be implemented in a plurality of specific environments. The described specific embodiments are only illustrative and do not limit the scope of the disclosure.

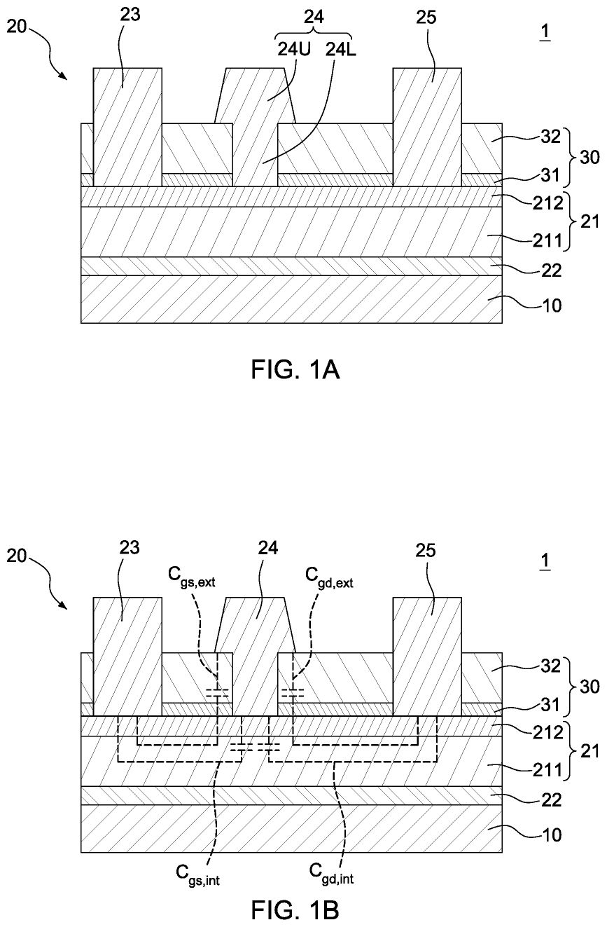

FIG. 1A illustrates a cross-sectional view of an electronic device 1, in accordance with some embodiments of the present disclosure.

Referring to FIG. 1A, the electronic device 1 may include a substrate 10 and a transistor 20.

The substrate 10 may be a bulk semiconductor substrate. The substrate 10 may be a silicon substrate. Alternatively, the substrate 10 may include another elementary semiconductor, such as germanium, or a compound semiconductor including silicon carbide, gallium arsenide, gallium phosphide, indium phosphide, indium arsenide, and indium antimonide; an alloy semiconductor, such as SiGe, GaAsP, AlInAs, AlGaAs, GalnAs, GaInP, and GaInAsP; and combinations thereof. The substrate 10 may be a silicon on insulator (SOI), an epitaxial material, or other suitable materials.

The transistor 20 may include a GaN-based HEMT. The electronic devices of the present disclosure can be applied in, without limitation, HEMT devices, low voltage HEMT devices, high voltage HEMT devices and radio frequency (RF) HEMT devices, microwave and mm-wave power amplifier and switchers.

The transistor 20 may include a semiconductor heterostructure layer 21, which may be a group III nitride semiconductor heterostructure layer. The semiconductor heterostructure layer 21 can be III-V compound layers. The semiconductor heterostructure layer 21 may include nitride semiconductor layer 211 and nitride semiconductor layer 212.

The nitride semiconductor layer 211 is disposed on the substrate 10. The nitride semiconductor layer 211 may be adjacent to the substrate. The nitride semiconductor layer 211 may include a group III-V layer. The nitride semiconductor layer 211 may include, but is not limited to, a group III nitride, for example, a compound InₓAl_{y}Ga_{1-x-y}N, in which x+y≤1. The group III nitride further includes, but is not limited to, for example, a compound Al_{y}Ga_{(1-y)}N, in which y≤1. The nitride semiconductor layer 211 includes a gallium nitride (GaN) layer. GaN has a band gap of about 3.4 V. The thickness of the nitride semiconductor layer 211 ranges, but is not limited to, from about 0.5 μm to about 10 μm.

The nitride semiconductor layer 212 is disposed on the nitride semiconductor layer 211. The nitride semiconductor layer 212 may be adjacent to the nitride semiconductor layer 211. The nitride semiconductor layer 212 may include a group III-V layer. The nitride semiconductor layer 212 may include, but is not limited to, a group III nitride, for example, a compound InₓAl_{y}Ga_{1-x-y}N, in which x+y≤1. The group III nitride further includes, but is not limited to, for example, a compound Al_{y}Ga_{(1-y)}N, in which y≤1. The nitride semiconductor layer 212 has a greater bandgap than that of the nitride semiconductor layer 211. The nitride semiconductor layer 212 includes an aluminum gallium nitride (AlGaN) layer. AlGaN has a band gap of about 4.0 V. The thickness of the nitride semiconductor layer 212 ranges, but is not limited to, from about 10 nm to about 100 nm.

In the transistor 20, the nitride semiconductor layer 211 can be referred to as a channel layer, and the nitride semiconductor layer 212 can be referred to as a barrier layer. A heterojunction is formed between the nitride semiconductor layer 211 and nitride semiconductor layer 212. Polarization of the heterojunction can form a two-dimensional electron gas (2DEG) in the nitride semiconductor layer 211 adjacent to the interface between nitride semiconductor layer 212 and the nitride semiconductor layer 164. The 2DEG is formed in a layer with a relatively small bandgap, such as the semiconductor layer 211 which includes GaN.

The transistor 20 may further include a buffer layer 22. The buffer layer 22 may be disposed between the substrate 10 and the nitride semiconductor layer 211. The buffer layer 22 may be adjacent to the substrate 10. The buffer layer 22 may be adjacent to the nitride semiconductor layer 211. The buffer layer 22 may be configured to reduce defects due to the dislocation between the substrate 10 and the subsequently formed III-V compound layer. The buffer layer 22 may include, but is not limited to, nitride, such as AlN, AlGaN or the like.

The transistor 20 further includes electrodes 23, 24, 25. The electrode 23 may be referred to as a source electrode. The electrode 24 may be referred to as a gate electrode. The electrode 25 may be referred to as a drain gate. The gate electrode 24 may be disposed between the source electrode 23 and the drain electrode 25.

The 2DEG formed in the nitride semiconductor layer 211 would be the carrier channel between the source and drain of the transistor 20.

The electrodes 23, 24, 25 may be disposed directly on the nitride semiconductor layer 212. The electrode 23, 24, 25 may be adjacent to the nitride semiconductor layer 212. The electrode 23, 24, 25 may be in direct contact with the nitride semiconductor layer 212.

The electrodes 23, 24, 25 may include titanium (Ti), tantalum (Ta), tungsten (W), aluminum (Al), cobalt (Co), copper (Cu), nickel (Ni), platinum (Pt), lead (Pb), molybdenum (Mo) and compounds thereof (such as, but not limited to, titanium nitride (TiN), tantalum nitride (TaN), other conductive nitrides, or conductive oxides), metal alloys (such as aluminum-copper alloy (Al—Cu)), or other suitable materials.

The gate electrode 24 may be disposed directly on the semiconductor heterostructure layer 21. The gate electrode 24 may directly contact the semiconductor heterostructure layer 21. Therefore, the gate electrode 24 can control the carrier channel between source and drain of the transistor rapidly so as to improve high speed performance of the electronic device 1.

The gate electrode 24 may be a T-shape gate electrode. The T-shape gate electrode may include an upper portion 24U and a lower portion 24L. The T-shape gate electrode may include an upper portion 24U with a wide head. The T-shape gate electrode may include a lower portion 24L with a thin leg. The T-shape gate electrode can suppress the electric field on the gate edge and reduce the parasitic capacitance between the gate and the drain. The T-shape gate electrode may lead to higher operation frequency. The application of a T-shape gate electrode 24 onto the transistor 20 can achieve high breakdown voltage for high frequency operation.

The transistor 20 may further include a multi-layer passivation 30. The multi-layer passivation 30 can be disposed on the semiconductor heterostructure layer 21. The multi-layer passivation 30 may be disposed directly on the nitride semiconductor layer 212. The multi-layer passivation 30 may be adjacent to the nitride semiconductor layer 212. The multi-layer passivation 30 may be in contact with the nitride semiconductor layer 212.

The polarization effects in the transistor 20 lead to a surface state having an unfavorable impact on device performance. When the surface of the semiconductor heterostructure layer 21 is not passivated, positively charged surface donor states can trap electrons and form a “virtual gate” that depletes the 2DEG, significantly reducing drain current. This phenomenon is called “current collapse.” The multi-layer passivation 30 can reduce the trapping effects and prevent the formation of the virtual gate.

The multi-layer passivation 30 may include a surface state compensating layer 31 and a low-k dielectric layer 32.

The surface state compensating layer 31 may be directly disposed on the nitride semiconductor layer 212. The surface state compensating layer 31 may be adjacent to the nitride semiconductor layer 212. The surface state compensating layer 31 may be in contact with the nitride semiconductor layer 212.

The surface state compensating layer 31 may reduce the surface state density of the nitride semiconductor layer 212. The surface state compensating layer 31 can compensate for the defects of the nitride semiconductor layer 212. It should be noted that, due to the application of the surface state compensating layer 31, the surface state density of the nitride semiconductor layer 212 may range between approximately 10⁸ cm⁻² and approximately 10¹² cm⁻². It should also be noted that, due to the application of the surface state compensating layer 31, the surface state density of the nitride semiconductor layer 212 may range between approximately 10⁸ cm⁻² and approximately 10¹¹ cm⁻².

The surface state compensating layer 31 may include silicon nitride, such as SiN, Si₃N₄. The surface state compensating layer 31 may be referred to as a silicon nitride layer. Due to the application of the silicon nitride layer, the surface state density of the nitride semiconductor layer 212 may range between approximately 10⁸ cm⁻² and approximately 10¹⁰ cm⁻². It should be noted that, if the surface state compensating layer 31 includes SiN a current leakage from carrier channel to electrodes 23, 24, 25 can be further eliminated.

The low-k dielectric layer 32 is disposed on the surface state compensating layer 31. The low-k dielectric layer 32 may be directly disposed on the surface state compensating layer 31. The low-k dielectric layer 32 may be adjacent to the surface state compensating layer 31. The low-k dielectric layer 32 may be in contact with the surface state compensating layer 31.

In comparison with the surface state compensating layer 31, the low-k dielectric layer 32 has a lower dielectric constant. The dielectric constant of the low-k dielectric layer 32 may be less than 4.2.

The low-k dielectric layer 32 may include carbon. The low-k dielectric layer 32 may include SiOCH. The low-k dielectric layer 32 may include p-type SiOCH. The low-k dielectric layer 32 may include SiOF. The low-k dielectric layer 32 may include Hydrogen silsesquioxane (HSQ). The low-k dielectric layer 32 may include methyl silsesquioxane (MSQ).

The thickness of the low-k dielectric layer 32 may be greater than the thickness of the surface state compensating layer 31. The thickness of the low-k dielectric layer 32 may be approximately 10 times the thickness of the silicon nitride layer 31. The thickness of the low-k dielectric layer 32 may be greater than 10 times the thickness of the silicon nitride layer 31. The surface state compensating layer 31 may have a thickness ranging from approximately 1 nm to approximately 10 nm. The low-k dielectric layer 32 may have a thickness ranging from approximately 10 nm to approximately 1000 nm. The low-k dielectric layer 32 may have a thickness ranging from approximately 10 nm to approximately 500 nm. The low-k dielectric layer 32 may have a thickness ranging from 10 nm to approximately 200 nm.

The electronic device 1 can operate at a frequency greater than 1 GHz. The electronic device 1 can operate at a frequency greater than 6 GHz. The electronic device 1 can operate at a frequency greater than 30 GHz. The electronic device 1 can operate between 1 GHz to 30 GHz. The electronic device 1 can operate between 1 GHz to 6 GHz.

Table 1 shows different embodiments of the electronic device 1 according to the present invention for different operation frequencies.

| Operation | Thickness | Thickness |
|---|---|---|
| frequency | of SiOCH | of SiN |
| <6 GHz | 10-200 nm | 1-10 nm |
| 6 GHz-30 GHz | 10-500 nm | 1-10 nm |
| >30 GHz | 10-1000 nm | 1-10 nm |

FIG. 1B illustrate equivalent capacitors provided by the electronic device 1.

As shown in FIG. 1B, the transistor 20 may have intrinsic gate-to-source capacitance C_{gs,int} and intrinsic gate-to-drain capacitance C_{gd,int}. The transistor 20 may have extrinsic gate-to-source capacitance C_{gs,ext} and extrinsic gate-to-drain capacitance C_{gd,ext}. The differences between the extrinsic capacitances C_{gs,ext}, C_{gd,ext}, and the intrinsic capacitances C_{gs,int}, C_{gd,int} are caused by the bulk of the passivation layer being disposed on the semiconductor heterostructure layer 21. The passivation layer will cause unavoidable and unwanted parasitic capacitance, which will cause adverse effects for device performance when the electronic device operates at high frequency.

Table 2 shows C_{gs,ext} observed under various operation frequencies of the electronic device and various conditions of passivation, with same total thickness, and disposed on the semiconductor heterostructure layer.

TABLE 1

| | | p-type | |
|---|---|---|---|
| Operation | SiOCH 145 nm | SiOCH 145 nm | SiN |
| frequency | with SiN 5 nm | with SiN 5 nm | 150 nm |
| <6 GHz | 0.1 pF/mm | 0.08 pF/mm | 0.3 pF/mm |
| 6 GHz-30 GHz | 0.05 pF/mm | 0.04 pF/mm | 0.15 pF/mm |
| >30 GHz | 0.01 pF/mm | 0.008 pF/mm | 0.03 pF/mm |

According to Table 1, comparing to passivation with only SiN, it is noted that the presence of a low-k layer, such as SiOCH or p-type SiOCH, can reduce C_{gs,ext}.

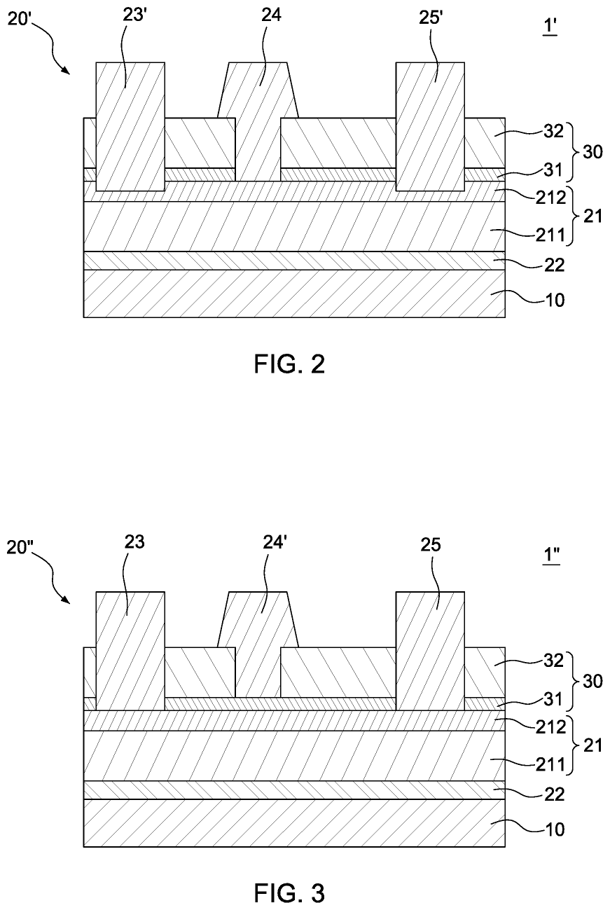

FIG. 2 illustrates an electronic device 1′ in accordance with some embodiments of the present disclosure. The electronic device 1′ has a structure similar to the electronic device 1 of FIG. 1A, with one difference being that the source electrode 23′ and the drain electrode 25′ may extend into the semiconductor heterostructure layer 21. A terminal of the source electrode 23′ may be disposed in the nitride semiconductor layer 212. A terminal of the drain electrode 25′ may be disposed in the nitride semiconductor layer 212. The interfaces between the electrodes 23′, 25′ and the nitride semiconductor layer 212 may form Ohmic contact. The interface between the gate electrode 24 and the nitride semiconductor layer 212 may form a Schottkey barrier. The arrangement of electrodes 23′, 25′ disposed in nitride semiconductor layer 212 may reduce gate-to-source capacitance C_{gs} and gate-to-drain capacitance C_{gd}, and the resistance between the electrodes 23′, 25′ and 2DEG can be reduced.

FIG. 3 illustrates an electronic device 1″ in accordance with some comparative embodiments of the present disclosure. The electronic device 1″ has a structure similar to the electronic device 1 of FIG. 1A, with one difference being that the gate electrode 24′ of the transistor 20″ is not disposed directly on the semiconductor heterostructure layer 21. The gate electrode 24′ of the transistor 20″ is not in contact with the nitride semiconductor layer 212. The gate electrode 24′ is disposed on the surface state compensating layer 31. The surface state compensating layer 31 separates the gate electrode 24′ and the nitride semiconductor layer 212. The surface state compensating layer 31 between the gate electrode 24′ and the semiconductor heterostructure layer 21 will cause a capacitance between the gate electrode 24′ and the semiconductor heterostructure layer 21. The capacitance will reduce the operation speed of the transistor 20″.

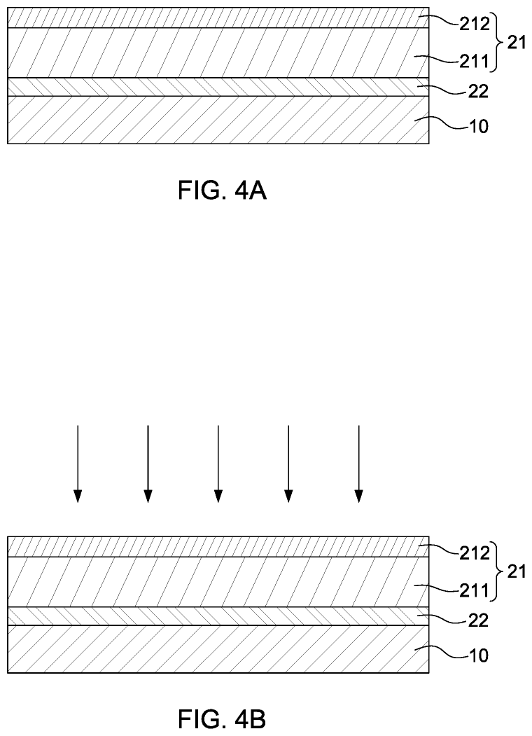

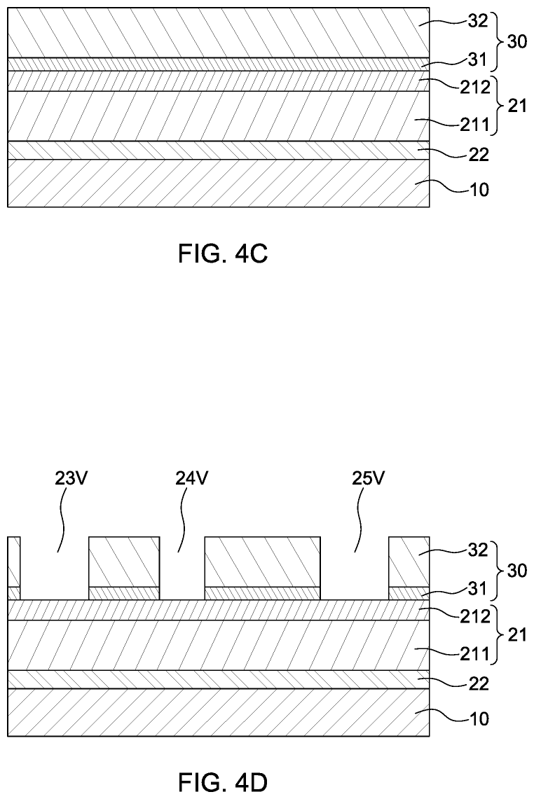

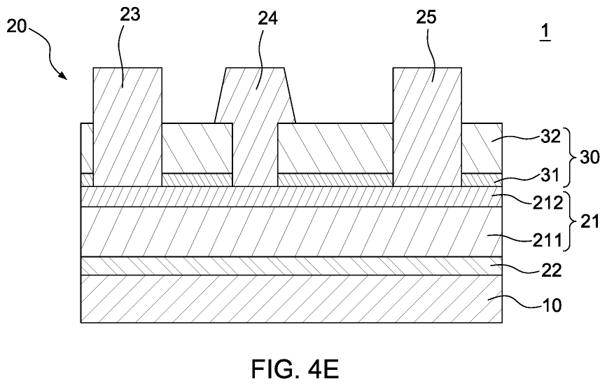

FIG. 4A, FIG. 4B, FIG. 4C and FIG. 4D illustrate various steps of a method for manufacturing an electronic device 1 in accordance with some embodiments of the present disclosure.

Referring to FIG. 4A, substrate 10 is provided. A buffer layer 22 and a semiconductor heterostructure layer 21 can be formed on the substrate 10. The semiconductor heterostructure layer 21 may include a nitride semiconductor layer 211 and a nitride semiconductor layer 212. The buffer layer 22, nitride semiconductor layer 211 and/or nitride semiconductor layer 212 may be formed by metal organic chemical vapor deposition (MOCVD), metal organic vapor-phase epitaxy (MOVPE), epitaxial growth, or other suitable processes.

Referring to 4B, a plasma treatment may be applied on the surface of the nitride semiconductor layer 212. The plasma treatment may be applied with remote plasma. The plasma treatment may be applied with low power. The elements in the plasma may include nitrogen. The plasma treatment may compensate for surface defects of the nitride semiconductor layer 212.

Referring to FIG. 4C, a surface state compensating layer 31 may be formed directly on the nitride semiconductor layer 212. The surface state compensating layer 31 may be silicon nitride layer. The surface state compensating layer 31 may be formed through a deposition step. The surface state compensating layer 31 may be formed on the nitride semiconductor layer 212 through CVD and/or another suitable deposition step.

A low-k dielectric layer 32 may be formed on the surface state compensating layer 31. The low-k dielectric layer 32 may be formed once the surface state compensating layer 31 is formed on the nitride semiconductor layer 212. The low-k dielectric layer 32 may be formed after forming the surface state compensating layer 31.

The surface state compensating layer 31 and the low-k dielectric layer 32 forms a multi-layer passivation 30.

Referring to FIG. 4D, vias 23V, 24V, 25V are formed in the multi-layer passivation 30. The vias 23V, 24V, 25V may be formed by, for example, but are not limited to, etching or other suitable techniques. The etching technique may include, for example, but is not limited to, dry etching, such as anisotropic etching. The etching step causes portions of the nitride semiconductor layer 212 to be exposed.

Referring to FIG. 4E, the vias 23V, 24V, 25V are at least partially filled with conductive material to form electrodes 23, 24, 25. The electrodes 23, 24, 25 may be formed through physical vapor deposition (PVD), atomic layer deposition (ALD) and/or another suitable deposition step. The electrodes 23, 24, 25 may be deposited directly on the nitride semiconductor layer 212. The electrodes 23, 24, 25 may be surrounded by the multi-layer passivation 30.

The electrode 24 may be formed with two steps: forming a lower portion 24L and forming an upper portion 24U. The upper portion 24U may be formed to be a wide head. The upper portion 24U may extrude a surface of the multi-layer passivation 30, and laterally extend on the surface of the multi-layer passivation 30.

The electronic device 1 of FIG. 4E is the same as that of FIG. 1A.

As used herein, for ease of description, space-related terms such as “under,” “below,” “lower portion,” “above,” “upper portion,” “lower portion,” “left side,” “right side,” and the like may be used to describe a relationship between one component or feature and another component or feature as shown in the figures. In addition to orientations shown in the figures, space-related terms are intended to encompass different orientations of the device in use or operation. A device may be oriented in other ways (rotated 90 degrees or at other orientations), and the space-related descriptors used herein may also be used for explanation accordingly. It should be understood that when a component is “connected” or “coupled” to another component, the component may be directly connected to or coupled to another component, or an intermediate component may exist.

As used herein, terms “approximately,” “basically,” “substantially,” and “about” are used for describing and considering a small variation. When being used in combination with an event or circumstance, the term may refer to a case in which the event or circumstance occurs precisely, and a case in which the event or circumstance occurs approximately. As used herein with respect to a given value or range, the term “about” generally means in the range of ±10%, ±5%, ±1%, or ±0.5% of the given value or range. The range may be indicated herein as being from one endpoint to another endpoint or between two endpoints. Unless otherwise specified, all the ranges disclosed in the disclosure include endpoints. The term “substantially coplanar” may refer to two surfaces within a few micrometers (μm) positioned along the same plane, for example, within 10 μm, within 5 μm, within 1 μm, or within 0.5 μm located along the same plane. When reference is made to “substantially” the same numerical value or characteristic, the term may refer to a value within ±10%, ±5%, ±1%, or ±0.5% of the average of the values.

Several embodiments of the disclosure and features of details are briefly described above. The embodiments described in the disclosure may be easily used as a basis for designing or modifying other processes and structures for realizing the same or similar objectives and/or obtaining the same or similar advantages introduced in the embodiments of the disclosure. Such equivalent constructions do not depart from the spirit and scope of the disclosure, and various variations, replacements, and modifications can be made without departing from the spirit and scope of the disclosure.

What is claimed is:

1. An electronic device, comprising:
a substrate; and
a transistor, comprising:
a first nitride semiconductor layer disposed on the substrate;
a second nitride semiconductor layer disposed on the first nitride semiconductor layer and having a bandgap greater than that of the first nitride semiconductor layer; and
a source electrode, a drain electrode and a gate electrode disposed directly on the second nitride semiconductor layer; and
a multi-layer passivation disposed on the second nitride semiconductor layer,
wherein the multi-layer passivation comprises a surface state compensating layer directly disposed on the second nitride semiconductor layer and a low-k dielectric layer disposed on the surface state compensating layer.

2. The electronic device of claim 1, wherein the surface state compensating layer comprises SiN.

3. The electronic device of claim 1, wherein the low-k dielectric layer comprises carbon.

4. The electronic device of claim 1, wherein the low-k dielectric layer comprises SiOCH.

5. The electronic device of claim 1, wherein a thickness of the low-k dielectric layer is greater than a thickness of the surface state compensating layer.

6. The electronic device of claim 1, wherein the low-k dielectric layer is approximately 10 times the thickness of the surface state compensating layer.

7. The electronic device of claim 1, wherein the surface state compensating layer has a thickness ranging from approximately 1 nm to approximately 10 nm.

8. The electronic device of claim 7, wherein the low-k dielectric layer has a thickness ranging from approximately 10 nm to approximately 1000 nm.

9. The electronic device of claim 7, wherein the low-k dielectric layer has a thickness ranging from approximately 10 nm to approximately 500 nm.

10. The electronic device of claim 7, wherein the low-k dielectric layer has a thickness ranging from approximately 10 nm to approximately 200 nm.

11. The electronic device of claim 1, wherein the low-k dielectric layer comprises at least one of following group: SiOF, Hydrogen silsesquioxane (HSQ), and methyl silsesquioxane (MSQ).

12. An electronic device, comprising:
a substrate;
a first nitride semiconductor layer disposed on the substrate;
a second nitride semiconductor layer disposed on the first nitride semiconductor layer and having a bandgap greater than that of the first nitride semiconductor layer; and
a multi-layer passivation disposed on the second nitride semiconductor layer, wherein the multi-layer passivation comprises a silicon nitride layer directly disposed on the second nitride semiconductor layer and a low-k dielectric layer disposed on the silicon nitride layer layer.

13. The electronic device of claim 12, wherein the low-k dielectric layer comprises carbon.

14. The electronic device of claim 12, wherein the low-k dielectric layer comprises SiOCH.

15. The electronic device of claim 12, wherein the low-k dielectric layer is approximately 10 times the thickness of the silicon nitride layer.

16. The electronic device of claim 12, wherein the silicon nitride layer has a thickness ranging from approximately 1 nm to approximately 10 nm.

17. The electronic device of claim 16, wherein the low-k dielectric layer has a thickness ranging from approximately 10 nm to approximately 1000 nm.

18. The electronic device of claim 16, wherein the low-k dielectric layer has a thickness ranging from approximately 10 nm to approximately 500 nm.

19. The electronic device of claim 16, wherein the low-k dielectric layer has a thickness ranging from approximately 10 nm to approximately 200 nm.

20. A method for forming an electronic device, comprising:
providing a substrate,
forming a first nitride semiconductor layer on a substrate,
forming a second nitride semiconductor layer on the first nitride semiconductor layer, wherein the second nitride semiconductor layer has a bandgap greater than that of the first nitride semiconductor layer; and
forming a multi-layer passivation on the second nitride semiconductor layer, comprising:
forming a silicon nitride layer directly on the second nitride semiconductor layer, and
forming a low-k dielectric layer on the silicon nitride layer; and
forming a source electrode, a gate electrode and a drain electrode of a transistor, wherein the gate electrode directly on the second nitride semiconductor layer.

21. The method of claim 20, further comprising implementing plasma treatment with nitrogen prior to forming the multi-layer passivation on the second nitride semiconductor layer.
